(19) United States
(12) Patent Application Publication
(10) Pub. No.: US 2020/0273807 A1
(43) Pub. Date: Aug. 27, 2020

(54) SEMICONDUCTOR PACKAGE WITH SILICON CRYSTAL STRUCTURE

(71) Applicant: Samsung Electronics Co., Ltd., Suwon-si (KR)

(72) Inventors: Dong Hoon WON, Cheonan-si (KR); Jae Kyung YOO, Seoul (KR)

(21) Appl. No.: 16/513,944

(22) Filed: Jul. 17, 2019

(30) Foreign Application Priority Data
Feb. 21, 2019 (KR) 10-2019-0020187

(51) Int. Cl. H01L 23/544; H01L 21/762; H01L 21/768

(52) U.S. Cl. CPC H01L 23/544; H01L 2223/5446; H01L 21/76898; H01L 21/76243

(57) ABSTRACT

A semiconductor package includes a substrate having a silicon crystal structure, and at least one semiconductor chip provided on the substrate and having an upper surface, a lower surface, and a plurality of side surfaces, wherein the plurality of side surfaces are different from cleavage planes of the substrate.

### CROSS-REFERENCE TO RELATED APPLICATION

This application claims the benefit of priority under 35 U.S.C. § 119 from Korean Patent Application No. 10-2019-0020187, filed on Feb. 21, 2019, in the Korean Intellectual Property Office, the disclosure of which is incorporated herein by reference in its entirety.

### BACKGROUND

### 1. Field

Apparatuses and methods consistent with the according to example embodiments relate to a wafer-level package in which semiconductor chips are mounted on a substrate having a silicon crystalline structure.

### 2. Description of Related Art

A wafer may be divided into a chip region, in which semiconductor chips are arranged on a surface of the wafer, and a scribe lane region for identifying the chip region and may include a flat zone FZ displaying a crystal structure of the wafer. Because the crystal structure of the wafer cannot be identified with the naked eye, in the flat zone FZ of the wafer, part of an outer circumferential surface of the wafer is flattened by being cut along a specific crystal plane to display a crystal orientation of the wafer. Generally, a scribe lane is parallel with or perpendicular to the flat zone FZ.

A wafer-level package may be formed by mounting semiconductor chips on a surface of a wafer and performing a dicing process of cutting a scribe lane region to separate the semiconductor chips from each other. During the manufacture of the wafer-level package, a bending force may be applied to the wafer due to an impact by the semiconductor chips or due to foreign substances. Cracks may occur in the wafer due to the bending force and propagate mainly in the crystal orientation of the wafer.

### SUMMARY

The example embodiments of the inventive concept are directed to providing a semiconductor package capable of preventing propagation of cracks due to a bending force applied to a wafer due to an impact caused when semiconductor chips are mounted on the wafer or due to foreign substances during the manufacture of a wafer-level package.

According to example embodiments, there is provided a semiconductor package including a buffer substrate having a silicon crystal structure, and at least one semiconductor chip provided on the buffer substrate and having an upper surface, a lower surface, and a plurality of side surfaces, wherein the plurality of side surfaces are at oblique angles with respect to cleavage planes of the buffer substrate. According to example embodiments, there is provided a semiconductor package including a silicon substrate having a silicon crystal structure and a {100} crystal plane as a main surface, and a semiconductor chip provided on the silicon substrate and having a tetragonal upper surface, wherein the semiconductor chip has an outer side surface forming an oblique angle with respect to a <110> crystal orientation of the silicon crystal structure when viewed in a plan view.

According to example embodiments, there is provided a method of manufacturing a semiconductor package, the method including preparing a buffer substrate having a silicon crystal structure and a (100) crystal plane as a main surface, arranging semiconductor chips on the buffer substrate, forming a molding member to cover the buffer substrate and the semiconductor chips, and forming individual semiconductor packages by dicing the molding member and the buffer substrate such that each of the individual semiconductor packages include at least one semiconductor chip, wherein the arranging of the semiconductor chips on the buffer substrate includes arranging the semiconductor chips such that outer side surfaces of the semiconductor chip form a 45° angle with respect to a <110> crystal orientation.

### BRIEF DESCRIPTION OF THE DRAWINGS

FIG. 1 is a schematic plan view illustrating a layout of a wafer and semiconductor chips and a semiconductor package individualized from the wafer, according to an example embodiment of the inventive concept.

FIG. 2 is a cross-sectional view taken along line I-I′ of FIG. 1.

FIG. 3 is a schematic plan view illustrating a layout of a wafer and semiconductor chips and a semiconductor package individualized from the wafer, according to an example embodiment of the inventive concept.

FIG. 4 is a schematic plan view illustrating a layout of a wafer and semiconductor chips and a semiconductor package individualized from the wafer, according to an example embodiment of the inventive concept.

FIGS. 5 to 10 are diagrams schematically illustrating a method of manufacturing a semiconductor package, according to an example embodiment of the inventive concept, in which FIG. 6 is a cross-sectional view taken along line II-IP of FIG. 5, FIG. 8 is a cross-sectional view taken along line of FIG. 7, and FIG. 10 is a cross-sectional view taken along line IV-IV′ of FIG. 9.

### DETAILED DESCRIPTION OF EXEMPLARY EMBODIMENTS

Hereinafter, exemplary embodiments of the inventive concept will be described in detail with reference to the accompanying drawings to clearly explain the technical idea of the inventive concept. In the following description, well-known functions or constructions related to the inventive concept are not described in detail if it is determined that they would obscure the inventive concept due to unnecessary detail. In the drawings, the same reference numerals or signs are assigned to components having substantially the same functions, if possible, although the components are illustrated in different drawings. For convenience of explanation, apparatuses and methods are described together when necessary.

In the technical idea of the inventive concept, crystal planes of a silicon wafer and crystal orientations thereof are main constituent elements. For understanding of the inventive concept, a crystallographic direction and crystallographic planes will be first described below.

Regarding Crystallographic Direction

A crystallographic direction may be represented using a vector and may be represented as [uvw] in a square bracket using the values of u, v, and w indicating a length of a vector projected onto x, y, and z axes which are the axes of coordinates. Each of the three axes may have positive and negative coordinates. A negative index may be represented using a bar above a corresponding index. For example, a [11̅1] direction has a negative component in a y-axis direction. In some crystal structures, non-parallel directions with some different directional indices are actually equivalent. This means that the interatomic distances in various directions are equal. For example, in a cubic structure, [100], [1̅00], [010], [01̅0], [001] and [001̅] are equivalent. For convenience of explanation, equivalent directions are referred to together as a family and may be expressed in chevron brackets. In the above case, the equivalent directions may be expressed as <100>. In a cubic crystal, directions having indices of the same group are the same regardless of the order or signs of the indices. For example, [123] and [213] are equivalent. This relationship does not apply to other crystal systems. For example, in a tetragonal crystal system, [100] and [010] are equivalent but [100] and [001] are different.

Regarding Crystallographic Plane

The planes of a crystal structure may be specified similar to the crystallographic direction. (hkl) Miller indices are used for all crystal systems using a three-axis coordinate system, except a hexagonal system. Two parallel planes are equivalent to each other and have the same index. A method of determining indices h, k, and 1 will be described below. (1) When a plane passes through the center of the axes of selected coordinates, the plane should be moved to another plane parallel thereto through appropriate parallel movement, or the center of a new coordinate axis should be created on another unit cell. (2) Through the above process, a crystallographic plane will meet three axes or be placed in parallel. Here, the distances between points of the axes intersecting the plane and the center are expressed with lattice constants a, b, and c. (3) Reciprocals of the obtained numbers a, b, and c are calculated. The axis parallel to the plane is assumed to meet the plane at infinity and thus is set to zero. (4) The three reciprocals are multiplied or divided by a common number to be changed to a group of minimum integers such as h, k, and l. (5) Finally, integer indices are expressed without a comma in a round bracket. That is, the integer indices are expressed as (hkl).

A negative direction of the origin is expressed by adding a bar or a negative sign to an index thereof. An opposite sign of each index represents a plane, which is located parallel to a certain plane, spaced the same distance as the certain plane in an opposite direction. In a cubic structure, a plane and a direction each having the same index are perpendicular to each other. However, in other crystal systems, such a simple relationship between a plane and a direction is not present.

An arrangement of atoms in a crystal plane depends on a crystal structure. In many planes with different indices, atomic packing factors may be equal but vary according to degrees of symmetry of crystal systems thereof. In the case of an atomic sphere model, the atomic packing factor refers to a volume fraction in a unit cell that is occupied by the atomic sphere. Such planes belong to a family of equivalent atomic planes. For example, in a cubic system, (111), (1̅11), (ĪĪĪ), (IĪĪ), (111̅), (1̅1̅1), and (1̅11̅) planes belong to a <111> family. On the other hand, in a hexagonal structure, a <100> family consists of only (100), (100), (010) and (01̅0) planes, because they are not crystallographically identical to the (001) and (001̅) planes. In addition, in the cubic system, indices of same values of different orders and different negative/positive signs may be the same. For example, (12̅3) and (3̅12) planes belong to a <123> family.

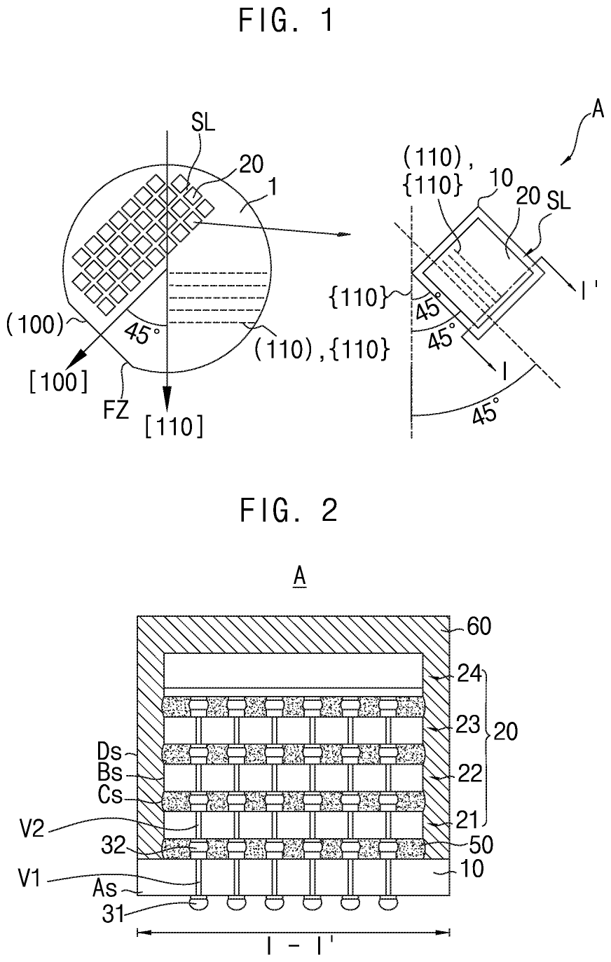

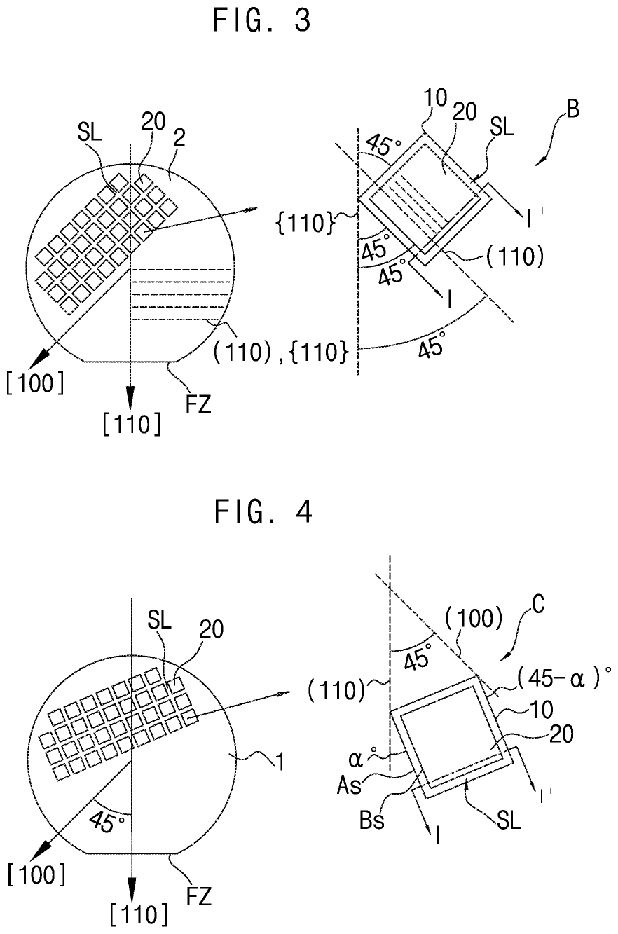

FIG. 1 is a schematic plan view illustrating a layout of a wafer and semiconductor chips and a semiconductor package individualized from the wafer according to an example embodiment of the inventive concept. FIG. 2 is a cross-sectional view taken along line I-I′ of FIG. 1.

Referring to FIGS. 1 and 2, a semiconductor package A according to an example embodiment of the inventive concept may be a wafer-level package in which semiconductor chips 20 are stacked on a buffer substrate 10 having a silicon crystal structure. The semiconductor package A, which is a wafer-level package, may be formed by separating the semiconductor chips 20 stacked on a wafer 1 by a dicing process. A semiconductor package according to the inventive concept is not limited to the semiconductor package A of FIG. 2. The inventive concept is applicable to various types of semiconductor packages in which a buffer substrate 10 is provided and at least one semiconductor chip 20 is mounted on the buffer substrate 10. The buffer substrate 10 may also be referred to as a package substrate. Each semiconductor chip 20 may be a die having an integrated circuit formed thereon, and each semiconductor chip 20 may be formed from a wafer.

In one example embodiment, the semiconductor package A may include the buffer substrate 10, first to fourth semiconductor chips 21, 22, 23, and 24, connection bumps 31 and 32, through-silicon vias TSVs V1 and V2, an insulating layer 50, and a molding member 60.

The buffer substrate 10 may be formed by cutting the wafer 1. For example, the buffer substrate 10 may be a portion of the wafer 1 that is separated and individualized by cutting the wafer 1. Thus, the buffer substrate 10 may have the same crystal orientation as the wafer 1. The buffer substrate 10 may be formed of a single crystal material and include, for example, a silicon substrate having a cubic crystal structure (or a silicon crystal structure). The buffer substrate 10 may be a rectangular parallelepiped having tetragonal upper and lower surfaces and four outer side surfaces. The buffer substrate 10 may include a plurality of outer side surfaces. The outer side surfaces of the buffer substrate 10 may include any of the outer side surfaces that are substantially perpendicular to upper and lower surfaces of the buffer substrate 10 and that extend between the upper and lower surfaces of the buffer substrate 10. The outer side surfaces of the buffer substrate 10 may include outer side surface As, as illustrated in FIG. 2.

The outer side surface As of the buffer substrate 10 may form an oblique angle with cleavage planes of the silicon crystal structure. Silicon splits along a specific crystal plane (i.e., a cleavage plane) or a specific crystal orientation when damaged (e.g., impacted, broken, cut, etc.). The specific crystal plane is called a cleavage plane. Cleavage planes of silicon are known as a {110} crystal plane and a {111} crystal plane. A {100} crystal plane also may be a cleavage plane of silicon, although it is slower than the {110} crystal plane and the {111} crystal plane in terms of a crack propagation speed. For example, when the silicon is damaged along the {110} crystal plane, a direction in which fissures (i.e., cracks) of the silicon are grown and propagate may be the same as a <110> crystal orientation. When the silicon is damaged along the {111} crystal plane, a direction in which the cracks of the silicon are grown and propagate may be the same as a <111> crystal orientation. When the silicon is damaged along the {100} crystal plane, a direction in which the cracks of the silicon are grown and propagate may be the same as a <100> crystal orientation.

In one example embodiment, the outer side surface As of the buffer substrate 10 may form an oblique angle with the (110) crystal plane or the <110> crystal orientation (i.e., the [110] crystal orientation, a [−110] crystal orientation, a [1−10] crystal orientation, and a [−1−10] crystal orientation). For example, the oblique angle may be 45°.

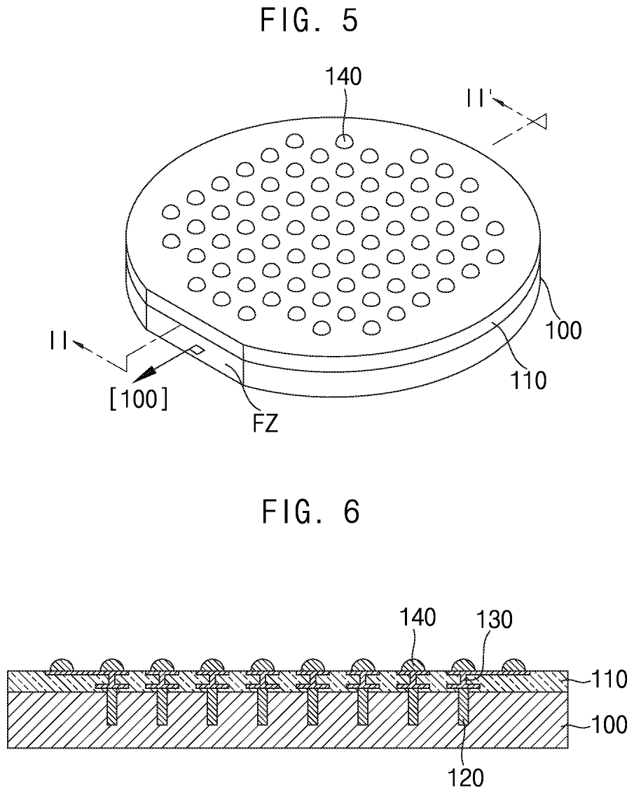

The semiconductor chips 20 may be mounted on an upper surface of the buffer substrate 10. The semiconductor chips 20 may include the first to fourth semiconductor chips 21, 22, 23, and 24. The first to fourth semiconductor chips 21, 22, 23, and 24 may be stacked on the buffer substrate 10 in a direction perpendicular to a main surface of the buffer substrate 10. For example, the first to fourth semiconductor chips 21, 22, 23, and 24 may be stacked on an upper surface of the buffer substrate 10. In some embodiments, the semiconductor chips 20 may be alternatively stacked with a plurality of insulating layers 50. Although FIG. 3 illustrates, for example, the semiconductor package A on which the four semiconductor chips 21, 22, 23, and 24 are stacked, the number of semiconductor chips stacked on the semiconductor package A is not limited to four.

The semiconductor chip 20 may be a rectangular parallelepiped having tetragonal upper and lower surfaces and four outer side surfaces Bs, similar to the buffer substrate 10. Each of the outer side surfaces Bs may be substantially planar, and each of the outer side surfaces Bs may be substantially perpendicular to the top surface of the buffer substrate 10. The semiconductor chips 20 may be arranged on the buffer substrate 10 such that the outer side surfaces Bs are parallel with the outer side surface As of the buffer substrate 10. The outer side surfaces Bs of the semiconductor chip 20 may form an oblique angle with the cleavage planes of the silicon crystal structure, similar to the outer side surface As of the buffer substrate 10. In one embodiment, an outer side surface Bs of the semiconductor chip 20 may form an oblique angle with the (110) crystal plane or the <110> crystal orientation (i.e., the [110] crystal orientation, the [410] crystal orientation, the [1−10] crystal orientation, and the [−1−10] crystal orientation. For example, the oblique angle may be 45°.

For example, the semiconductor chip 20 may be a memory semiconductor chip. The memory semiconductor chip may be a volatile memory semiconductor chip such as a dynamic random access memory (DRAM) or a static RAM (SRAM), or a nonvolatile memory semiconductor chip such as a phase-change RAM (PRAM), a magneto-resistive RAM (MRAM), a ferroelectric RAM (FeRAM) or a resistive RAM (RRAM). In an embodiment, the first to fourth semiconductor chips 21, 22, 23, and 24 may be high-bandwidth memory (HBM) DRAM semiconductor chips.

The connection bumps 31 and 32 may include lower connection bumps 31 and upper connection bumps 32. The lower connection bumps 31 may be arranged on a lower surface of the buffer substrate 10. The upper connection bumps 32 may be interposed between the buffer substrate 10 and the first semiconductor chip 21, between the first and second semiconductor chips 21 and 22, between the second and third semiconductor chips 22 and 23, and between the third and fourth semiconductor chips 23 and 24, and may electrically connect the first to fourth semiconductor chips 21, 22, 23, and 24. For example, the connection bumps 31 and 32 may include at least one of conductive pads, solder balls, or solder bumps.

The lower connection bumps 31 may be arranged on a lowermost surface of the semiconductor package A and may be chip-substrate connection bumps for mounting the semiconductor package A on an external substrate or an interposer. The lower connection bumps 31 may be supplied with at least one of a control signal, a power signal or a ground signal for operating the first to fourth semiconductor chips 21, 22, 23, and 24 from the outside, may be supplied with a data signal to store data in the first to fourth semiconductor chips 21, 22, 23, and 24 from the outside, or may provide data stored in the first to fourth semiconductor chips 21, 22, 23, and 24 to the outside.

The TSVs V1 and V2 may include first TSVs V1 and second TSVs V2. The first TSVs V1 may extend from the upper surface of the buffer substrate 10 to the lower surface of the buffer substrate 10. The second TSVs V2 may extend from the upper surfaces of the first to third semiconductor chips 21, 22, and 23 to the lower surfaces of the first to third semiconductor chips 21, 22, and 23, respectively. At least some of the TSVs V1 and V2 may have a column shape.

The insulating layer 50 may be interposed between the buffer substrate 10 and the first semiconductor chip 21, interposed between the first and second semiconductor chips 21 and 22, interposed between the second and third semiconductor chips 22 and 23, and interposed between the third and fourth semiconductor chips 23 and 24. The insulating layer 50 may surround side surfaces of the upper connection bumps 32. As illustrated in FIG. 2, an outer side surface Cs of the insulating layer 50 may protrude by a certain width toward an outer side of the semiconductor chip 20. However, the inventive concept is not limited thereto. The outer side surface Cs of the insulating layer 50 may extend along the outer side surface Bs of the semiconductor chip 20. For example, the outer side surface Cs of the insulating layer 50 may be substantially co-extensive and/or parallel with the outer side surface Bs of the semiconductor chip 20. In one embodiment, a direction in which the outer side surface Cs of the insulating layer 50 extends may form an oblique angle with the cleavage planes of the silicon crystal structure of the buffer substrate 10. For example, the insulating layer 50 may include an underfill material such as an insulating polymer, an epoxy resin, or the like.

The molding member 60 may surround side surfaces of the insulating layer 50 and side surfaces of the first to fourth semiconductor chips 21, 22, 23, and 24. The molding member 60 may be formed to a certain thickness on the upper surface of the fourth semiconductor chip 24. A lower surface of the molding member 60 may be formed on a portion of the upper surface of the substrate 10. For example, the molding member 60 may be formed on portions of the substrate 10 that extend beyond the area of the first to fourth semiconductor chips 21, 22, 23, and 24 stacked thereon. Alternatively, unlike that illustrated in FIG. 2, the molding member may not be formed on the upper surface of the fourth semiconductor chip 24 and the upper surface of the fourth semiconductor chip 24 may be exposed outside the semiconductor package A. For example, the molding member 60 may include an epoxy mold compound (EMC) or the like. An outer side surface ds of the molding member 60 may form the same plane as the outer side surface As of the buffer substrate 10.

Referring to FIG. 1, in one embodiment, in the wafer 1, the flat zone FZ may be formed perpendicular to or parallel with the [100] crystal orientation of the wafer 1. For example, the flat zone FZ may have the same plane as the (100) crystal plane of the wafer 1. When the wafer 1 with the flat zone FZ having the same plane as the (100) crystal plane is used in process equipment for regularly arranging the semiconductor chips 20 along a normal direction of the flat zone FZ with respect to the flat zone FZ, the semiconductor chips 20 may be arranged in a line on the wafer 1 along the [100] crystal orientation. In this case, a side surface of each of the semiconductor chips 20 may be parallel with the [100] crystal orientation of the wafer 1 and may form a 45° angle with the [110] crystal orientation of the wafer 1. The scribe lanes SL may extend in the <100> crystal orientation of the wafer 1 to form the 45° angle with the [110] crystal orientation. When the wafer 1 is diced along the scribe lanes SL extending in the <100> crystal orientation of the wafer 1, the semiconductor package A having a side surface, which forms an oblique angle with the cleavage plane (i.e., the {110} crystal plane) of the wafer 1 and the <110> crystal orientation, may be formed.

Conventionally, semiconductor chips are arranged in a <110> crystal orientation on a wafer, the main surface of which is a (100) crystal plane and the flat zone FZ of which has a (110) crystal plane, and a scribe lane extends in the <110> crystal orientation. Thus, in the case wherein cracks occur in the wafer in the <110> crystal orientation, which is a cleavage orientation, due to an impact applied to the wafer when the semiconductor chips are mounted during the assembly of a semiconductor package, the cracks may easily propagate along the scribe lane. Thus, in the inventive concept, the semiconductor chips 20 are arranged in a direction forming an oblique angle with a cleavage orientation (or a cleavage plane) so that even when cracks occur in the wafer 1 in the cleavage direction, the propagation of the cracks may be prevented due to the semiconductor chips 20. For example, a plurality of semiconductor chips 20 may be arranged in an array on the wafer 1 such that the scribe lines SL are at an angle (e.g., a 45° angle) with the [110] crystal orientation. Accordingly, the manufacture yield of a semiconductor package may be greatly improved.

In one embodiment, at least one of the semiconductor chips 20 arranged on the buffer substrate 10 may have a silicon crystal structure similar to the buffer substrate 10 (or the wafer 1), and the semiconductor chips 20 may be arranged such that the <110> crystal plane of the semiconductor chips 20 forms an oblique angle with the cleavage planes of the wafer 1 or the buffer substrate 10. For example, the {110} crystal plane of the buffer substrate 10 of the semiconductor package A and the {110} crystal plane of the semiconductor chips 20 form a 45° angle with respect to one another.

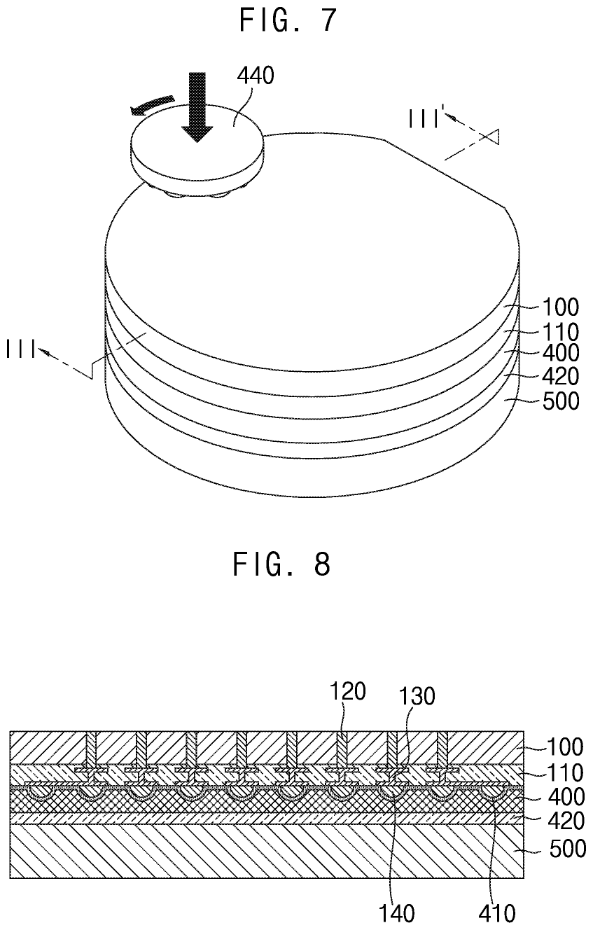

FIG. 3 is a schematic plan view illustrating a layout of a wafer and semiconductor chips and a semiconductor package individualized from the wafer, according to an example embodiment of the inventive concept. A cross-sectional view taken along line I-I′ of FIG. 3 may be the same as that taken along line I-I′ of FIG. 1. FIG. 4 is a schematic plan view illustrating a layout of a wafer and semiconductor chips and a semiconductor package individualized from the wafer, according to an example embodiment of the inventive concept. A cross-sectional view taken along line I-I′ of FIG. 4 may be the same as that taken along line I-I′ of FIG. 1. In FIGS. 1 to 4, the same reference numerals represent the same components and will not be redundantly described herein for the sake of a concise description.

Referring to FIG. 3, in one embodiment, a flat zone FZ may be formed on a wafer 1 to be perpendicular to or parallel with a [110] crystal orientation. That is, the flat zone FZ may have the same plane as a (110) crystal plane. When process equipment is used to regularly arrange semiconductor chips 20 in a [100] crystal orientation on the wafer 1 with the flat zone FZ having the same plane as the [110] crystal plane, the semiconductor chips 20 may be arranged in a line on the wafer 1 in the [100] crystal orientation. Alternatively, in a photolithography process, a direction of arrangement of a mask pattern may be set to be parallel to the [100] crystal orientation so that the semiconductor chips 20 may be arranged on the wafer 1 in the [100] crystal orientation. Similar to FIG. 1, a scribe lane SL may extend in the <100> crystal orientation to form 45° with the [110] crystal orientation. When the wafer 2 is diced along the scribe lane SL extending in the <100> crystal orientation, a semiconductor package B including a side surface forming an oblique angle with a cleavage plane (i.e., the {110} crystal plane) of the wafer 1 and the <110> crystal orientation may be formed.

In one embodiment, as described above with reference to FIG. 1, at least one of the semiconductor chips 20 arranged on a buffer substrate 10 of the semiconductor package B may have a silicon crystal structure, similar to the buffer substrate 10 (or the wafer 1), and the semiconductor chips 20 may be arranged such that {110} crystal planes (i.e., the (110) crystal planes) of the semiconductor chips 20 form an oblique angle with the cleavage plane (i.e., the {110} crystal plane) of the wafer 1 or the buffer substrate 10. For example, the {110} crystal plane of the buffer substrate 10 of the semiconductor package A and the {110} crystal planes of the semiconductor chips 20 may form a 45° angle with respect to one another.

Referring to FIG. 4, an outer side surface As of a semiconductor package C may form oblique angle α° with respect to each of a plurality of cleavage planes. The oblique angle α° may be greater than or equal to 1° and less than 45°. In some example embodiments, the oblique angle α° may be less than or equal to 44°. In one embodiment, the plurality of cleavage planes may include a {110} crystal plane and a {100} crystal plane. The outer side surface As of the semiconductor package C and an outer side surface Bs of each of the semiconductor chips 20 may be respectively different from the {110} crystal plane and the {100} crystal plane. For example, the outer side surface Bs of each of the semiconductor chips 20 may be at an oblique angle with respect to the {110} crystal plane and the {100} crystal plane.

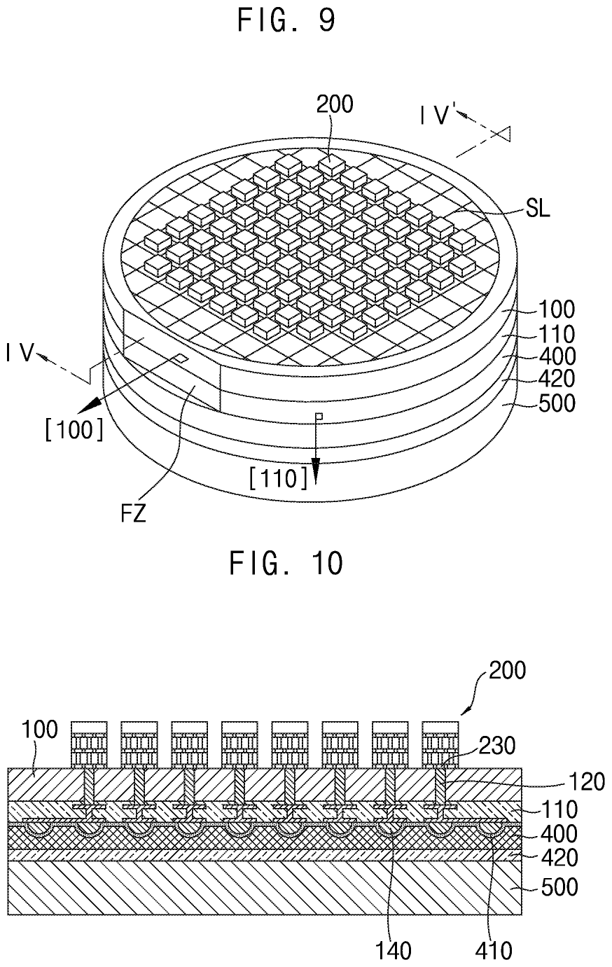

FIGS. 5 to 10 are diagrams schematically illustrating a method of manufacturing a semiconductor package according to an example embodiment of the inventive concept. FIG. 6 is a cross-sectional view taken along line II-II′ of FIG. 5. FIG. 8 is a cross-sectional view taken along line III-III′ of FIG. 7. FIG. 10 is a cross-sectional view taken along line IV-IV′ of FIG. 9.

Referring to FIGS. 5 and 6, TSVs 120 may be formed to pass through a silicon wafer 100 (also referred to as a silicon substrate), and an interconnection layer 110 may be formed on the silicon wafer 100. Although, for convenience of explanation, FIG. 6 illustrates that the TSV 120 has a column shape and is connected to a connection electrode 130, the inventive concept is not limited thereto, and a plurality of TSVs 120 may be formed and may be individually connected to the connection electrodes 130 according to an electrical signal. Connection electrodes 130 electrically connected to the TSVs 120 may be arranged in the interconnection layer 110. Connection bumps 140 electrically connected to the connection electrodes 130, respectively, may be formed on the interconnection layer 110. In one embodiment, the silicon wafer 100 may include a flat zone FZ or a notch (not shown). For example, a normal direction of the flat zone FZ may be equal to a <100> crystal orientation of a silicon crystal structure.

Referring to FIGS. 7 and 8, a release layer 410 covering the interconnection layer 110 and the connection bumps 140 may be formed, and a protective layer 400 may be formed on the layer 410. The release layer 410 is formed to easily remove the protective layer 400 and may be formed of a material having low adhesion with the wiring layer 110 and the connection bumps 140. For example, the release layer 410 may be formed of a polymer or a UV film. The release layer 410 may have a thickness smaller than that of the wiring layer 110. The protective layer 400 may cover the release layer 410. The protective layer 400 may protect the substrate 100 from the outside during the afterward process. The protective layer 400 may be formed of a material having high intensity, high thermal resistance, and high elastic coefficient. For example, the passivation layer 400 may comprise an epoxy series material, a thermoset material, a thermoplastic material, or a UV treatment material.

An adhesive layer 420 may be formed on a wafer carrier 500, and an upper surface of the protective layer 400 may be adhered to the adhesive layer 420 by turning over the silicon wafer 100 having the protective layer 400. The wafer carrier 500 may be a temporary carrier used to facilitate a process of stacking semiconductor chips and forming a molding member. An exposed surface of the silicon wafer 100 may be ground by a grinder 440 to expose the TSV 120.

Referring to FIGS. 9 and 10, a plurality of semiconductor chips 200 may be arranged on a surface of the silicon wafer 100. The plurality of semiconductor chips 200 may be electrically and/or physically connected to the TSVs 120. For example, the plurality of semiconductor chips 200 may be electrically and/or physically connected to the TSVs 120 through connection bumps 230. The plurality of semiconductor chips 200 may be arranged such that outer side surfaces thereof are located parallel with a [100] crystal orientation and at an angle with respect to a [110] crystal orientation. Although not shown in the drawings, a molding member 60 covering the plurality of semiconductor chips 200 and the wafer 100 may be formed thereafter. The wafer 100 may be inverted and the wafer carrier 500, the adhesive layer 420, the protective layer 400, and the release layer 410 may be removed. The wafer 100 and the molding member 60 along the scribe lanes SL can be diced into individual semiconductor packages. For example, dicing of the wafer 100 along the scribe line SL may be performed by dicing the wafer 100 along a direction that is 45° with respect to the <110> crystal direction of the wafer 100.

According to the example embodiments of the inventive concept, a crystal orientation of a substrate used in a wafer-level package and a direction of arrangement of semiconductor chips on the substrate may be controlled to prevent propagation of cracks that may occur in the substrate when the semiconductor chips are mounted on the substrate. Accordingly, a defect ratio during the manufacture of the wafer-level package may be reduced.

While the embodiments of the inventive concept have been described with reference to the accompanying drawings, it should be understood by those skilled in the art that various modifications may be made without departing from the scope of the inventive concept and without changing essential features thereof. Therefore, the above-described embodiments should be considered in a descriptive sense only and not for purposes of limitation.

What is claimed is:

1. A semiconductor package comprising:
a buffer substrate comprising a silicon crystal structure; and
at least one semiconductor chip provided on the buffer substrate and having an upper surface, a lower surface, and a plurality of side surfaces,
wherein the plurality of side surfaces are at oblique angles with respect to cleavage planes of the buffer substrate.

2. The semiconductor package of claim 1, wherein the cleavage planes of the buffer substrate comprise at least one of a {110} crystal plane, a {111} crystal plane, and a {100} crystal plane of the silicon crystal structure.

3. The semiconductor package of claim 1, wherein at least one of the plurality of side surfaces forms a 45° angle with respect to the cleavage planes of the buffer substrate.

4. The semiconductor package of claim 1,
wherein the cleavage planes of the buffer substrate comprise a {110} crystal plane and a {100} crystal plane of the silicon crystal structure, and
wherein at least one of the plurality of side surfaces forms an angle which is greater than 1° and less than 45° with respect to the {110} crystal plane.

5. The semiconductor package of claim 1,
wherein the buffer substrate comprises a {100} crystal plane of the silicon crystal structure as a main surface, and
wherein at least one of the plurality of side surfaces forms an oblique angle with respect to a {110} crystal plane, which is a cleavage plane of the buffer substrate.

6. The semiconductor package of claim 5, wherein the oblique angle is 45°.

7. The semiconductor package of claim 6, wherein at least one of the plurality of side surfaces is the same as the (100) crystal plane of the silicon crystal structure.

8. The semiconductor package of claim 1,
wherein the buffer substrate comprises scribe lanes extending to surround the at least one semiconductor chip when viewed in a plan view, and
wherein a direction in which the scribe lanes extends form an oblique angle with a crystal orientation of the silicon crystal structure.

9. The semiconductor package of claim 1,
wherein the at least one semiconductor chip comprises a silicon crystal structure, and
wherein a {110} crystal plane of the silicon crystal structure forms an oblique angle with respect to the cleavage planes of the buffer substrate.

10. The semiconductor package of claim 1, wherein the at least one semiconductor chip comprises a plurality of through-silicon-vias (TSVs) therein.

11. The semiconductor package of claim 10,
wherein the at least one semiconductor chip comprises a plurality of connection bumps electrically connected to the plurality of TSVs, and
wherein the plurality of connection bumps comprise at least one of a conductive pad, a solder ball, or a solder bump.

12. A semiconductor package comprising:
a silicon substrate comprising a silicon crystal structure, and a {100} crystal plane as a main surface; and
a semiconductor chip provided on the silicon substrate and having a tetragonal upper surface,
wherein the semiconductor chip comprises an outer side surface forming an oblique angle with respect to a <110> crystal orientation of the silicon crystal structure when viewed in a plan view.

13. The semiconductor package of claim 12, wherein the oblique angle is 45°.

14. The semiconductor package of claim 12, wherein the outer side surface extends in parallel with the <100> crystal orientation of the silicon crystal structure.

15. The semiconductor package of claim 12, wherein the semiconductor chip comprises a plurality of through-silicon-vias (TSVs) therein.

16. The semiconductor package of claim 15,
wherein the semiconductor chip comprises a plurality of connection bumps electrically connected to the plurality of TSVs, and
wherein the plurality of connection bumps comprise at least one of a conductive pad, a solder ball, or a solder bump.

17. The semiconductor package of claim 12, wherein in the semiconductor package, a plurality of semiconductor chips and a plurality of insulating layers are alternately stacked.

18. The semiconductor package of claim 17, wherein outer side surfaces of the plurality of insulating layers extend in a direction at an angle with respect to the <110> crystal orientation of the silicon crystal structure.

19. A method of manufacturing a semiconductor package, comprising:
preparing a buffer substrate comprising a silicon crystal structure and a (100) crystal plane as a main surface;
arranging semiconductor chips on the buffer substrate;
forming a molding member to cover the buffer substrate and the semiconductor chips; and
forming individual semiconductor packages by dicing the molding member and the buffer substrate such that each of the individual semiconductor packages comprises at least one semiconductor chip,
wherein the arranging of the semiconductor chips on the buffer substrate comprises arranging the semiconductor chips such that outer side surfaces of the semiconductor chip form a 45° angle with respect to a <110> crystal orientation.

20. The method of claim 19, wherein the forming of the individual semiconductor packages comprises dicing the buffer substrate in a direction forming the 45° angle with respect to the <110> crystal orientation.
